(19) United States
(12) Patent Application Publication
(10) Pub. No.: US 2026/0231550 A1
(43) Pub. Date: Aug. 6, 2026

(54) SOLID-STATE IMAGING DEVICE WITH PHASE DIFFERENCE DETECTION

(71) Applicant: Samsung Electronics Co., Ltd., Suwon-si (KR)

(72) Inventors: Kazufumi Shiozawa, Yokohama (JP); Takaaki Shimomura, Yokohama (JP); Takayuki Ogasahara, Yokohama (JP)

(21) Appl. No.: 19/461,311

(22) Filed: Jan. 27, 2026

(30) Foreign Application Priority Data
Jan. 29, 2025 (JP) 2025-012576
Dec. 16, 2025 (KR) 10-2025-0200539

(51) Int. Cl. H10F 39/00; H10F 39/18

(52) U.S. Cl. CPC H10F 39/807; H10F 39/182; H10F 39/805; H10F 39/8053; H10F 39/8063

(57) ABSTRACT

A solid-state imaging device includes a pixel array in which a plurality of pixels and one or more phase difference-detection pixels are arranged in a matrix, wherein the phase difference-detection pixel includes a photodiode, an on-chip lens, a light transmission layer, an anti-reflection layer, a light transmission layer separation wall, a pixel separation wall, a boundary separation wall, and a light separation wall arranged between the on-chip lens and the photodiode, and the light separation wall is arranged parallel with an extension direction of the boundary separation wall in a plane direction perpendicular to a stacking direction in the phase difference-detection pixel.

### CROSS-REFERENCE TO RELATED APPLICATIONS

This application is based on and claims priority under 35 U.S.C. §119 to Japanese Patent Application No. 2025-012576, filed on January 29, 2025, in the Japanese Patent Office and Korean Patent Application No. 10-2025-0200539, filed on December 16, 2025, in the Korean Intellectual Property Office, the disclosures of which are incorporated by reference herein in their entirety.

### BACKGROUND

Electronic apparatuses having an imaging function, such as digital cameras, smartphones, etc. may use solid-state imaging devices such as complementary metal-oxide semiconductor (CMOS) image sensors.

In a solid-state imaging device, an array of pixels array may include a phase difference-detection pixel that detects an image-plane phase difference in addition to a pixel that generates an image signal according to incident light.

### SUMMARY

The disclosure provides a solid-state imaging device in which a separation ratio of incident light incident onto a phase difference-detection pixel is improved.

In a phase difference-detection pixel, a separation ratio, which may be an indicator of the auto-focus (AF) performance, may decrease by a diffraction limit of incident light due to miniaturization of pixel arrays. Furthermore, in a phase difference-detection pixel, light scattering may occur by an interaction between incident light and a pixel separation wall on an incident surface of the incident light at a photoelectric conversion unit, which leads to increased mixed colors and decreased quantum efficiency (QE).

According to an aspect of the disclosure, there is provided a solid-state imaging device including a pixel array in which a plurality of pixels generating image signals according to incident light and one or more phase difference-detection pixels are arranged in a matrix, wherein each of the one or more phase difference-detection pixels may include a photoelectric conversion unit (also referred to as a “photosensor”), an on-chip lens arranged on an incident side of the incident light with respect to the photoelectric conversion unit, a light transmission layer transmitting light having a particular wavelength from the incident light, an anti-reflection layer stacked on the photoelectric conversion unit, a light transmission layer separation wall arranged between the light transmission layer and a light transmission layer of an adjacent pixel, a pixel separation wall arranged between the photoelectric conversion unit and a photoelectric conversion unit of the adjacent pixel, a boundary separation wall dividing the photoelectric conversion unit surrounded by the pixel separation wall into a plurality of parts, and a light separation wall arranged between the on-chip lens and the photoelectric conversion unit, and wherein the light separation wall may be arranged parallel with an extension direction of the boundary separation wall on a plane perpendicular to a stacking direction in the phase difference-detection pixel.

According to another aspect of the disclosure, there is provided a solid-state imaging device including a pixel array including a plurality of phase difference-detection pixels, wherein each of the plurality of phase difference-detection pixels may include an on-chip lens condensing received light, a light transmission layer transmitting light having a particular wavelength from incident light transmitted through the on-chip lens, a photodiode configured to photoelectric-covert light transmitted through the light transmission layer, an anti-reflection layer stacked between the light transmission layer and the photodiode, a light transmission layer separation wall arranged between the light transmission layer and a light transmission layer of an adjacent pixel, a pixel separation wall arranged between the photodiode and a photodiode of an adjacent pixel, a light separation wall dividing the light transmission layer into at least two parts, and a boundary separation wall separating the photodiode into at least two parts.

### BRIEF DESCRIPTION OF THE DRAWINGS

Implementations will be more clearly understood from the following detailed description taken in conjunction with the accompanying drawings.

FIG. 1 is a block diagram of a solid-state imaging device according to some implementations.

FIG. 2 is an enlarged plan view of a part of a solid-state imaging device according to some implementations.

FIG. 3 is a schematic cross-sectional view taken along line A1-A1 of FIG. 2.

FIG. 4 is a schematic cross-sectional view taken along line A2-A2 of FIG. 2.

FIG. 5 is a schematic cross-sectional view taken along line A5-A5 of FIG. 3.

FIG. 6 is a schematic cross-sectional view taken along line A4-A4 of FIG. 3.

FIG. 7 is a schematic cross-sectional view taken along line A5-A5 of FIG. 3.

FIG. 8A is a schematic diagram illustrating a state in which incident light is incident on a solid-state imaging device according to some implementations.

FIG. 8B is a schematic diagram illustrating light intensity distribution of incident light incident on a light transmission layer taken along line B1-B1 of FIG. 8A.

FIG. 8C is a schematic diagram illustrating light intensity distribution of incident light incident on a photoelectric conversion unit taken along line B2-B2 of FIG. 8A.

FIG. 9A is a diagram illustrating a configuration example of a phase difference-detection pixel according to some implementations, wherein (a) of FIG. 9A is a schematic view of a light transmission layer, and (b) of FIG. 9A is a schematic view of a photoelectric conversion unit.

FIG. 9B is a diagram illustrating a configuration example of a phase difference-detection pixel according to some implementations, wherein (a) of FIG. 9B is a schematic view of a light transmission layer, and (b) of FIG. 9B is a schematic view of a photoelectric conversion unit.

FIG. 9C is a diagram illustrating a configuration example of a phase difference-detection pixel according to some implementations, wherein (a) of FIG. 9C is a schematic view of a light transmission layer, and (b) of FIG. 9C is a schematic view of a photoelectric conversion unit.

FIG. 9D is a diagram illustrating a configuration example of a phase difference-detection pixel according to some implementations, wherein (a) of FIG. 9D is a schematic view of a light transmission layer, and (b) of FIG. 9D is a schematic view of a photoelectric conversion unit.

FIG. 9E is a diagram illustrating a configuration example of a phase difference-detection pixel according to some implementations, wherein (a) of FIG. 9E is a schematic view of a light transmission layer, and (b) of FIG. 9E is a schematic view of a photoelectric conversion unit.

FIG. 9F is a diagram illustrating a configuration example of a phase difference-detection pixel according to some implementations, wherein (a) of FIG. 9F is a schematic view of a light transmission layer, and (b) of FIG. 9F is a schematic view of a photoelectric conversion unit.

FIG. 10A is a schematic diagram of a phase difference-detection pixel arranged at a central portion of a pixel array according to some implementations.

FIG. 10B is a schematic diagram of a phase difference-detection pixel arranged at a peripheral portion of a pixel array according to some implementations.

FIG. 11A is a schematic cross-sectional view of a solid-state imaging device including a light separation wall according to some implementations.

FIG. 11B is a schematic cross-sectional view taken along line C1-C1 of FIG. 11A.

FIG. 11C is a schematic cross-sectional view taken along line C2-C2 of FIG. 11B.

FIG. 12A is a schematic cross-sectional view of a solid-state imaging device including a light separation wall according to some implementations.

FIG. 12B is a schematic cross-sectional view taken along line D1-D1 of FIG. 12A.

FIG. 12C is a schematic cross-sectional view taken along line D2-D2 of FIG. 12B.

FIG. 13A is a schematic cross-sectional view of a solid-state imaging device including a light separation wall according to some implementations.

FIG. 13B is a schematic cross-sectional view taken along line E1-E1 of FIG. 13A.

FIG. 13C is a schematic cross-sectional view taken along line E2-E2 of FIG. 13B.

FIG. 14A is a schematic cross-sectional view of a solid-state imaging device including a light separation wall according to some implementations.

FIG. 14B is a schematic cross-sectional view of a solid-state imaging device taken along line F1-F1 of FIG. 14A.

FIG. 15 is a schematic cross-sectional view of a phase difference-detection pixel according to some implementations.

FIG. 16 is a schematic cross-sectional view of a phase difference-detection pixel according to a comparative example.

FIG. 17 is a graph showing simulation results of a phase difference-detection pixel according to some implementations and a phase difference-detection pixel according to a comparative example.

### DETAILED DESCRIPTION

Hereinafter, implementations will be described in detail with reference to the accompanying drawings. In the drawings, like reference numerals denote like components, and sizes of components in the drawings may be exaggerated for clarity and convenience of explanation. Meanwhile, implementations described below are provided merely as an example, and various modifications may be made from the implementations.

Now, a solid-state imaging device 1 according to some implementations is described.

For convenience in explanation, the XYZ orthogonal coordinate system is set to the solid-state imaging device 1. A direction parallel with an X axis within a plane may be defined as an X-axis direction. A direction parallel with a Y axis perpendicular to the X axis within a plane may be defined as a Y-axis direction. A direction parallel with a Z axis perpendicular to each of the X axis and the Y axis may be defined as a Z-axis direction. In the implementations, the aforementioned plane may be parallel with a horizontal plane in an XY plane, and the Z axis may be in a vertical direction perpendicular to the aforementioned plane. Accordingly, the Z-axis direction may correspond to a stacking direction (thickness direction) of components constituting the solid-state imaging device 1, and the X-axis direction and the Y-axis direction may correspond to a plane direction perpendicular the stacking direction.

The solid-state imaging device 1 may include a pixel 10, a phase difference-detection pixel 20, and a chip substrate 100. The solid-state imaging device 1 may include a complementary metal-oxide semiconductor (CMOS) image sensor.

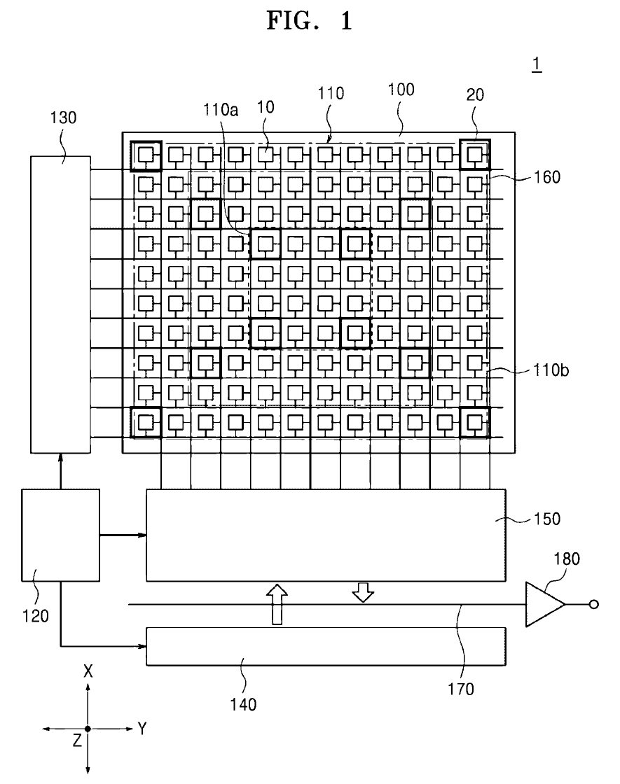

The solid-state imaging device 1 may include on the chip substrate 100 a pixel array 110 including a plurality of pixels 10 outputting a pixel signal (for example, image signal) and one or more phase difference-detection pixels 20 detecting an image-plane phase difference, as illustrated in FIG. 1. The pixel 10 and the phase difference-detection pixels 20 may have different structures. In some implementations, the pixel array 110 may include a plurality of phase difference-detection pixels 20 instead of the pixel 10, and the plurality of phase difference-detection pixels 20 may detect image-plane phase difference and also output image signals.

The solid-state imaging device 1 may include a control circuit 120 configured to generate an operation signal for operating each component, a vertical drive circuit 130 configured to enable scanning in a vertical direction that is a second direction perpendicular to a first direction of each pixel 10 (i.e., the Y-axis direction in the drawings) and control an output of a pixel signal according to a light-receiving amount of each pixel 10, a horizontal drive circuit 140 configured to output a scan pulse in a horizontal direction that is the first direction (i.e., the X-axis direction in the drawing), a column signal processing circuit 150 configured to generate a picture signal by processing a pixel signal output from each pixel 10, a vertical signal line 160 transmitting a pixel signal generated from each pixel 10 to the column signal processing circuit 150, a horizontal signal line 170 through which a pixel signal from the column signal processing circuit 150 is output, and an output circuit 180 configured to process a picture signal received through the horizontal signal line 170 and output a processed signal. In FIG. 1, an area surrounded by a thick line in the pixel array 110 may indicate the phase difference-detection pixel 20.

In addition, a central portion 110a of the pixel array 110 may refer to a certain range from the center of the pixel array 110 towards the outer edge portion of the pixel array 110, and a peripheral portion 110b of the pixel array 110 may refer to a certain range from the outermost edge of the pixel array 110 towards the center of the pixel array 110.

The chip substrate 100 may include silicon (Si), etc., and the pixel 10 and the phase difference-detection pixel 20 may be formed on the substrate. The chip substrate 100 may constitute a photoelectric conversion unit of the pixel 10 and a photoelectric conversion unit 25 of the phase difference-detection pixel 20. A photoelectric conversion unit can also be referred to as a photosensor. A pixel transistor, a wiring layer, etc. may be formed on a surface of the chip substrate 100, which is opposite to an incident surface of incident light L incident on the solid-state imaging device 1. The chip substrate 100 may output to the control circuit 120, etc. a pixel signal obtained by converting the incident light L received by the pixel 10 and the phase difference-detection pixel 20 into an electrical signal.

In the solid-state imaging device 1, components other than the phase difference-detection pixel 20 formed in the pixel array 110 may be arbitrarily or selectively employed from among the components publicly known in the field of solid-state imaging devices. Thus, in the disclosure, description of components other than the phase difference-detection pixel 20 may be omitted.

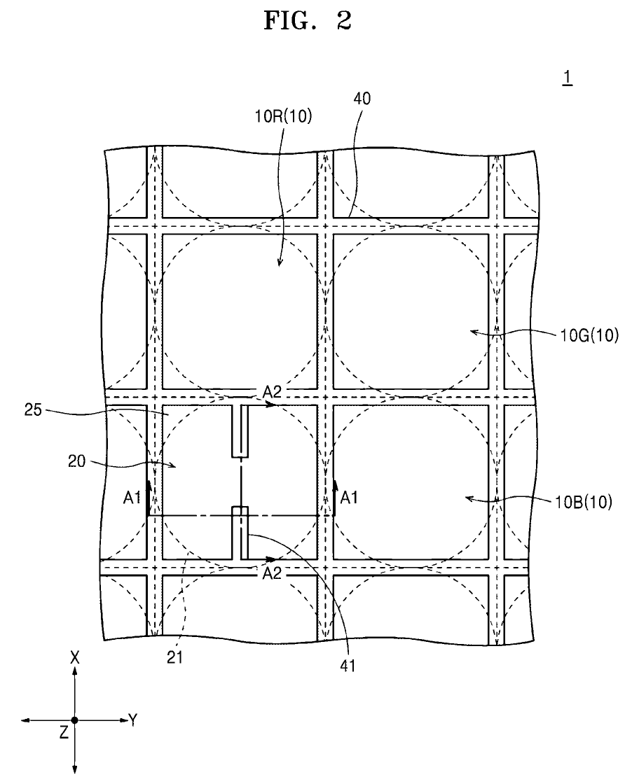

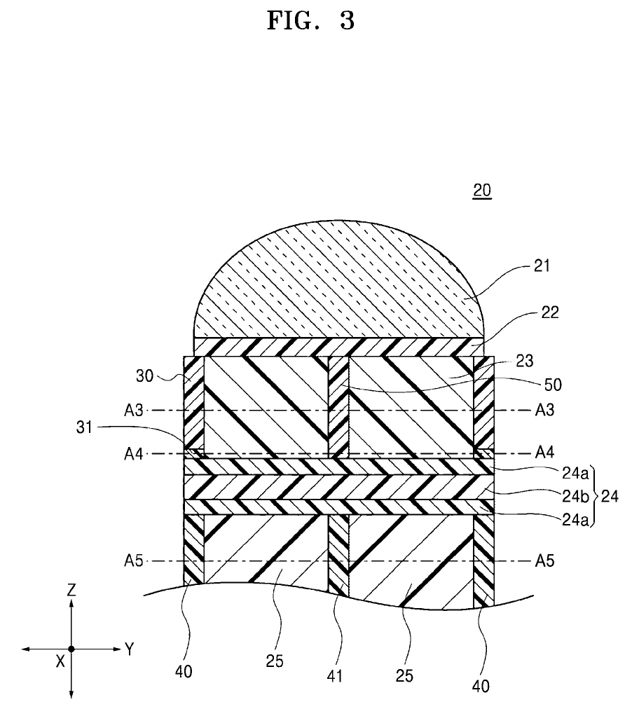

FIG. 2 illustrates an enlarged plan view of a part of the solid-state imaging device 1 according to some implementations, cut in the horizontal direction (cut in the XY plane). FIG. 3 is a schematic cross-sectional view of the solid-state imaging device 1 taken along line A1-A1 of FIG. 2.

The pixel 10 may include a red pixel 10R, a green pixel 10G, and a blue pixel 10B, as illustrated in FIG. 2. The pixel 10 may be arranged on the chip substrate 100 in a two-dimensional (2D) manner (for example, in a matrix). In the pixel array 110, the pixel 10 and the phase difference-detection pixel 20 may be arranged in the Bayer pattern. However, this is only an example, and a yellow filter, a magenta filter, and cyan filter may be included in the pixel array 110. In addition, in the pixel array 110, the arrangement positions and numbers of the pixels 10 and the phase difference-detection pixels 20 may be set in an arbitrary manner.

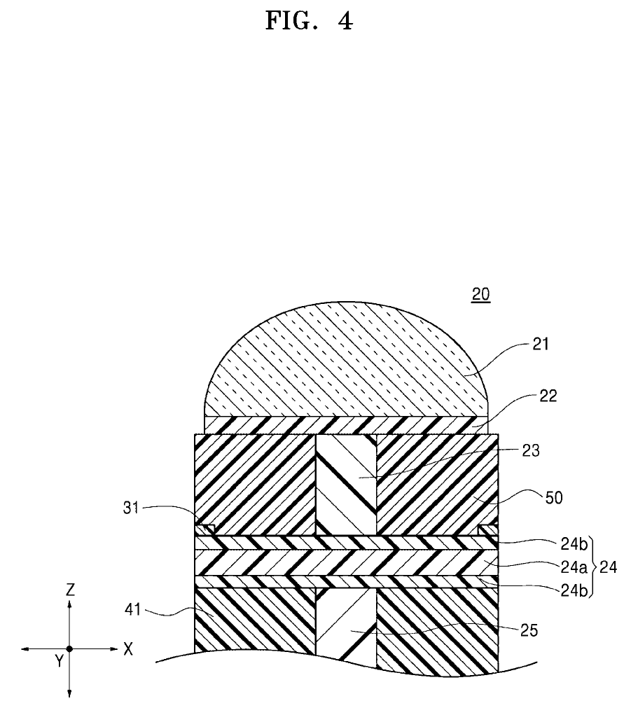

FIG. 4 is a schematic cross-sectional view of the solid-state imaging device 1 taken along line A2-A2 of FIG. 2. The phase difference-detection pixel 20 may include an on-chip lens 21, a planarization layer 22, a light transmission layer 23, an anti-reflection layer 24, a photoelectric conversion unit 25 (also referred to as a photosensor), a light transmission layer separation wall 30, a pixel separation wall 40, and a light separation wall 50. The phase difference-detection pixel 20 may be divided by the light transmission layer separation wall 30 or the pixel separation wall 40 and may be separated independently from each of adjacent pixels 10 and phase difference-detection pixels 20.

The phase difference-detection pixel 20 may have a structure in which the photoelectric conversion unit 25 is divided into a plurality of parts by a boundary separation wall 41. The phase difference-detection pixel 20 may detect a phase difference from the difference of a pixel signal based on a charge amount generated by the plurality of photoelectric conversion units 25. A deviation of a focus may be calculated based on the detected phase difference, and a camera lens may move based on the calculation result, thereby implementing auto-focusing. Therefore, an imaging device employing the solid-state imaging device 1 may not require a separate device for auto-focusing and may adjust a focus on an object based on the phase difference of light incident on the phase difference-detection pixel 20.

The on-chip lens 21 may be formed on the planarization layer 22. The on-chip lens 21 may be arranged in correspondence with each phase difference-detection pixel 20. For example, the on-chip lens 21 may be arranged in a 2D manner on a plane (for example, in a matrix). The on-chip lens 21 may have a convex shape and a certain radius of curvature to condense incident light IL onto the photoelectric conversion unit 25. The on-chip lens 21 may be formed by using an organic material such as styrene resin, acrylic resin, styrene-acrylic copolymer resin, siloxane reins, etc.

The planarization layer 22 may be formed between the on-chip lens 21 and the light transmission layer 23. The planarization layer 22 may have a high transmissivity with respect to the incident light L incident onto the photoelectric conversion unit 25 and may provide a planar surface for the on-chip lens 21. The planarization layer 22 may include an organic material such as resin, etc.

The light transmission layer 23 may be arranged between the planarization layer 22 and the photoelectric conversion unit 25 in a 2D manner (for example, in a matrix) in correspondence with each unit pixel. The light transmission layer 23 may be formed by adding a pigment or dye of desired color to resin having a low light absorptivity. The refractive index of the light transmission layer 23 may be about 1.6 to about 1.8.

The light transmission layer 23 may transmit light of a particular wavelength in a visible light range. The light transmission layer 23 may function as a color filter that transmits any one of red light, green light, and blue light and absorb the other lights. In addition, the light transmission layer 23 may function as a white filter that transmits light of almost all ranges of the visible light range as light of a particular wavelength.

The light transmission layer separation wall 30 having light-shielding properties may be arranged at the boundary between one light transmission layer 23 and another light transmission layer 23 adjacent thereto. In this manner, the light transmission layer 23 may be separated from adjacent pixel 10 or phase difference-detection pixel 20 for each pixel.

The anti-reflection layer 24 may be arranged between the light transmission layer 23 and the photoelectric conversion unit 25. The anti-reflection layer 24 may be formed by alternately stacking a high-refractive index layer 24a, including a material having a high refractive index (e.g., SiN, HfO, TaO, TiO, etc.), and a low-refractive index layer 24b, including a material having a low refractive index (e.g., SiO₂, AlO, etc.)

The anti-reflection layer 24 may be formed by alternately stacking the low-refractive index layer 24b and the high-refractive index layer 24a from, for example, an incident side of the incident light L, as illustrated in FIGS. 3 and 4. The stacked high-refractive index layers 24a may include the same material or different materials from each other. The stacked low-refractive index layers 24b may include the same material or different materials from each other. The anti-reflection layer 24 illustrated in FIG. 3 may have a stacked structure in which three layers, i.e., the low-refractive index layer 24b, the high-refractive index layer 24a, and the low-refractive index layer 24b are stacked in this order from the incident side of the incident light L. The stacking number of the high-refractive index layers 24a and the low-refractive index layers 24b in the anti-reflection layer 24 is not limited. However, at least the uppermost layer and the lowermost layer may each be the low-refractive index layer 24b.

The photoelectric conversion unit 25 may convert into an electrical signal the transmitted light of the incident light L, which has reached the photoelectric conversion unit 25 and is a target of photoelectric conversion. The photoelectric conversion unit 25 may have a structure in which the photoelectric conversion unit 25 is divided into a plurality of parts by the boundary separation wall 41. The photoelectric conversion unit 25 may include, for example, at least one of a photodiode, a phototransistor, a photogate, a pinned photodiode, an organic photodiode, quantum dots, and any combination thereof. However, the disclosure is not limited thereto.

The light transmission layer separation wall 30 may be formed to surround the light transmission layer 23 of the phase difference-detection pixel 20. The light transmission layer separation wall 30 may be arranged in a lattice form in a plan view and may divide and separate each layer to have a certain size by forming a boundary between adjacent pixels 10. The light transmission layer separation wall 30 may have a function of vignetting the incident light L incident onto the phase difference-detection pixel 20 and a function of shielding light from an adjacent pixel 10. Accordingly, the light transmission layer separation wall 30 may be formed to a height and a width suitable for the aforementioned functions. The light transmission layer separation wall 30 may include a dielectric material having a low light absorptivity, such as SiO₂, SiN, etc.

A light-shielding portion 31 may be formed between the light transmission layer separation wall 30 and the anti-reflection layer 24. The light-shielding portion 31 may be formed to surround the light transmission layer 23. As the light-shielding portion 31 is arranged between adjacent pixels 10 or phase difference-detection pixels 20, crosstalk between the adjacent pixels may be suppressed, and accordingly, the degree of precision in detecting a phase difference may be improved. The light-shielding portion 31 may include, for example, a metal material such as titanium nitride (TiN), titanium (Ti), tungsten (W), aluminum (Al), molybdenum (Mo), nickel (Ni), etc.

The pixel separation wall 40 may be formed by deep trench isolation (DTI). The pixel separation wall 40 may be arranged between the photoelectric conversion unit 25 and the photoelectric conversion unit 25 of an adjacent pixel and surround the photoelectric conversion unit 25 of the phase difference-detection pixel 20. In this manner, the photoelectric conversion unit 25 of the phase difference-detection pixel 20 may be isolated individually for each pixel.

The pixel separation wall 40 may include the boundary separation wall 41, which divides the photoelectric conversion unit 25 into a plurality of parts. The boundary separation wall 41 may divide the photoelectric conversion unit 25 into a certain number of parts such that an image-plane phase difference may be detected by the photoelectric conversion unit 25 in the phase difference-detection pixel 20.

In the solid-state imaging device 1 according to some implementations, the light separation wall 50 may be formed between the on-chip lens 21 and the photoelectric conversion unit 25, as illustrated in FIGS. 3 and 4.

The light separation wall 50 may divide the light transmission layer 23 in accordance with the number of divided photoelectric conversion units 25. The light separation wall 50 may be stacked on the anti-reflection layer 24 and may be arranged parallel with the boundary separation wall 41 in a plane direction, as illustrated in FIGS. 3 and 4. To clearly show the light separation wall 50 in the drawings, the boundary between the light separation wall 50 and the light transmission layer separation wall 30 may be marked with a broken line when necessary. However, the light separation wall 50 and the light transmission layer separation wall 30 may be formed in an integrated manner.

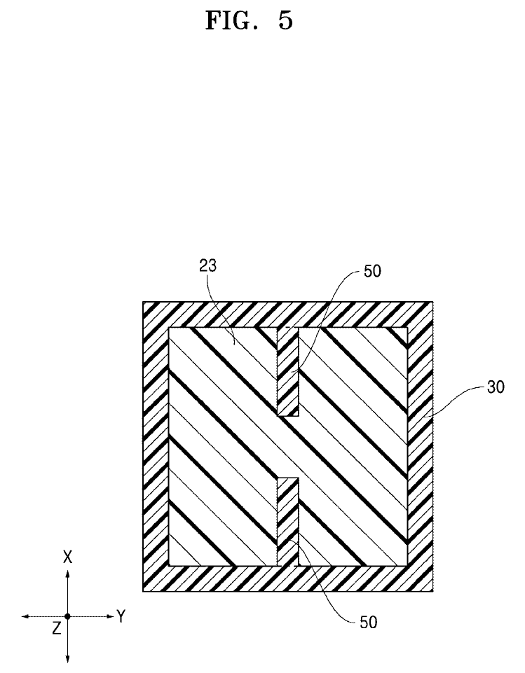

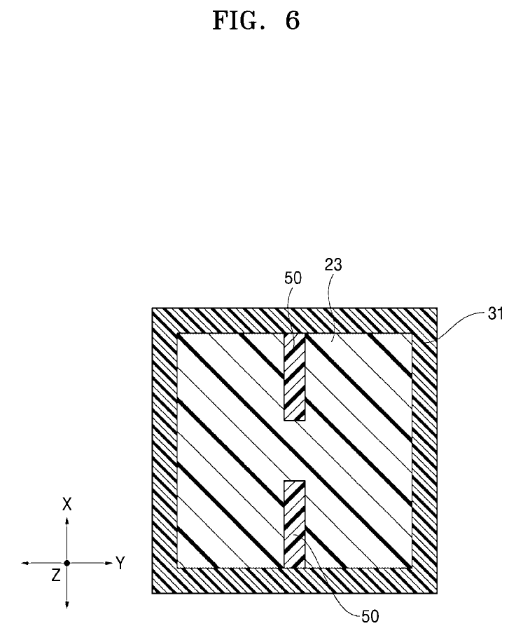

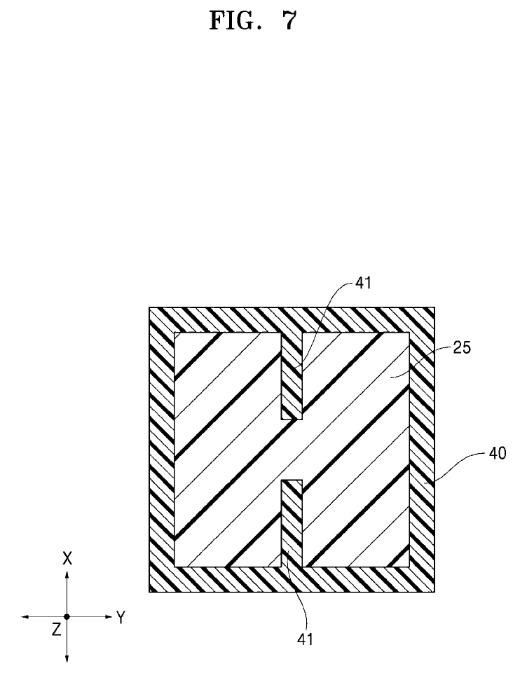

FIG. 5 is a plan view of the solid-state imaging device 1 taken along line A3-A3 of FIG. 3. FIG. 6 is a plan view of the solid-state imaging device 1 taken along line A4-A4 of FIG. 3. FIG. 7 is a plan view of the solid-state imaging device 1 taken along line A5-A5 of FIG. 3. The light separation wall 50 may be formed towards the on-chip lens 21 from the anti-reflection layer 24 of the light transmission layer 23, as illustrated in FIGS. 5 and 6. The light separation wall 50 may be formed in accordance with the position of the boundary separation wall 41 of the photoelectric conversion unit 25, as illustrated in FIGS. 5, 6, and 7.

The light separation wall 50 may include a dielectric material having a light absorption amount less than that of the light transmission layer 23, such as silicon oxide (SiO₂), etc. An attenuation coefficient may be used as an indicator of the "light absorption amount." The attenuation coefficient may refer to a value representing an absorption amount of light incident on a material, and when the value is large, it means that more light is absorbed, and the incident light is attenuated intensively.

As illustrated in FIGS. 4 and 5, the light separation wall 50 may be divided at the central portion of the phase difference-detection pixel 20 such that the optical path of the incident light L incident onto the center of the phase difference-detection pixel 20 is not interrupted. That is, the light separation wall 50 may not be formed at the central portion of the phase difference-detection pixel 20. Accordingly, the incident light L incident onto the central portion of the phase difference-detection pixel 20 may proceed directly to the light transmission layer 23.

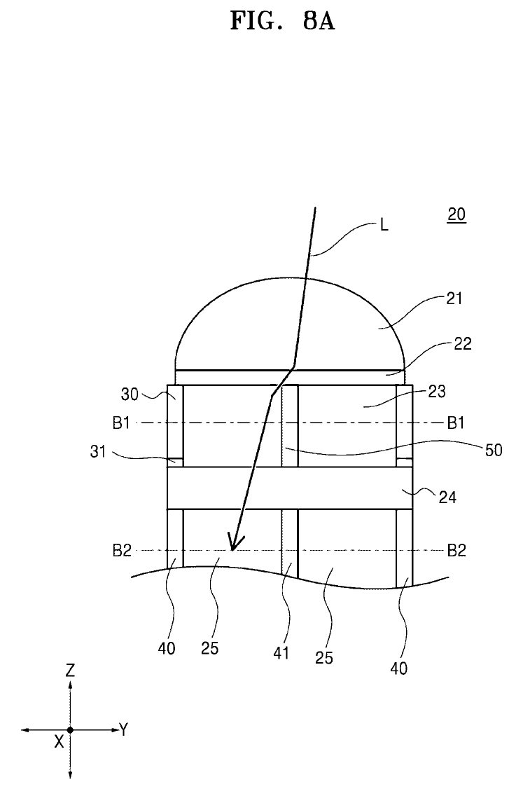

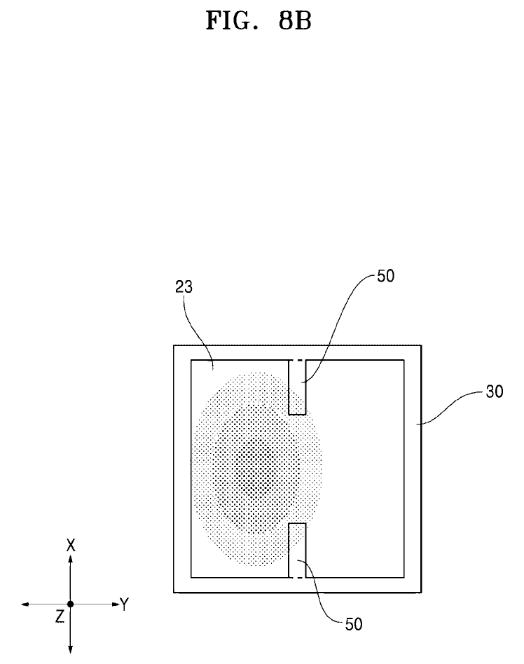

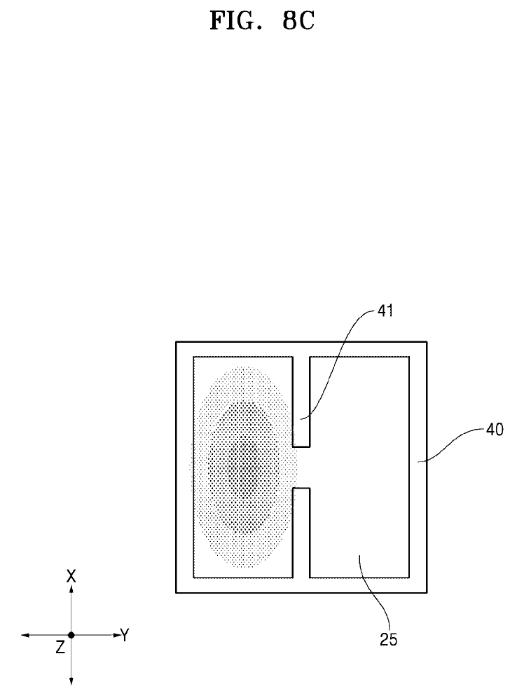

In the solid-state imaging device 1, the light separation wall 50 dividing the light transmission layer 23 may be arranged between the on-chip lens 21 and the photoelectric conversion unit 25. The light transmission layer 23, which has a high refractive index, and the light transmission layer separation wall 30 and the light separation wall 50, which have a low refractive index, may form an optical waveguide structure guiding the incident light L to the photoelectric conversion unit 25, as illustrated in FIG. 8A. The optical waveguide structure may guide, prior to incidence of the incident light L onto the photoelectric conversion unit 25, the optical path of the incident light L to any one photoelectric conversion unit 25.

FIG. 8B is a schematic diagram illustrating light intensity distribution of the incident light L incident on the light transmission layer 23 taken along line B1-B1 of FIG. 8A. FIG. 8C is a schematic diagram illustrating light intensity distribution of the incident light L incident on the photoelectric conversion unit 25 taken along line B2-B2 of FIG. 8A. In FIGS. 8B and 8C, the light intensity distribution is represented by an ellipse with dot hatching, and the light and shade of the dots represent light intensity. For convenience, cross-sectional hatching is omitted in the drawings.

In the solid-state imaging device 1, the light intensity distribution in the photoelectric conversion unit 25 may be skewed to one side by the optical waveguide structure, as illustrated in FIGS. 8B and 8C. Accordingly, the separation ratio at the phase difference-detection pixel 20 in the solid-state imaging device 1 may be improved.

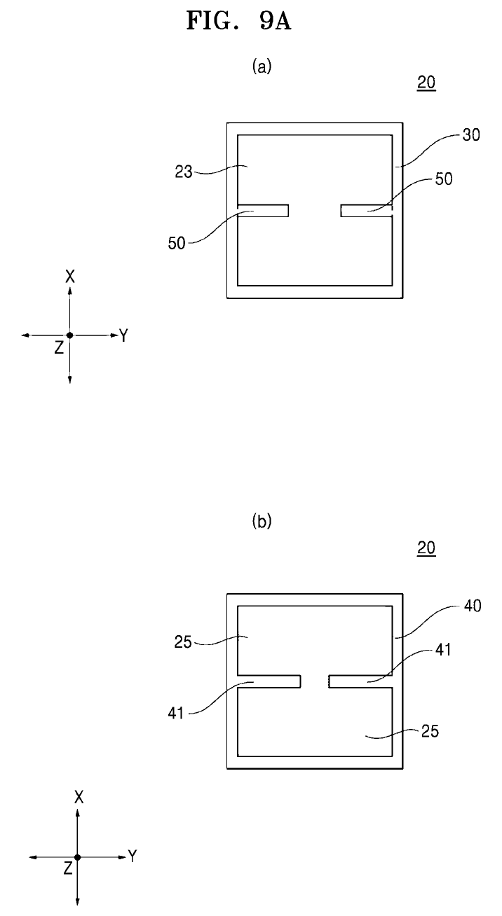

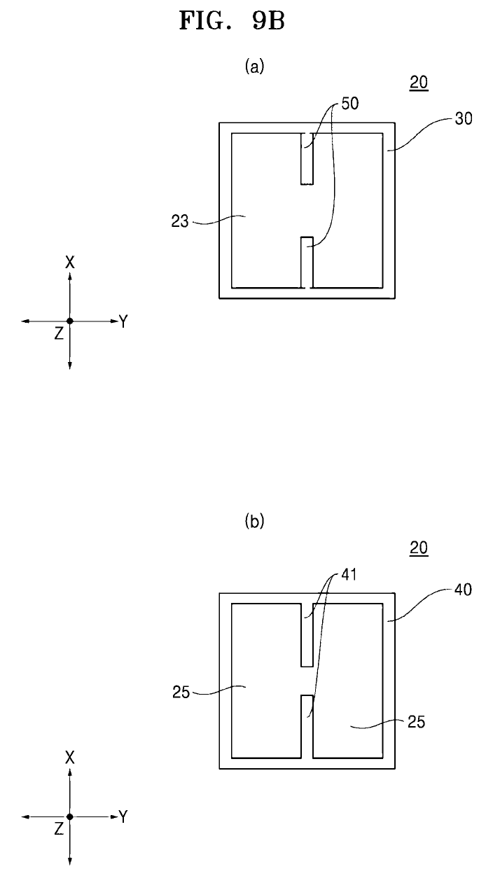

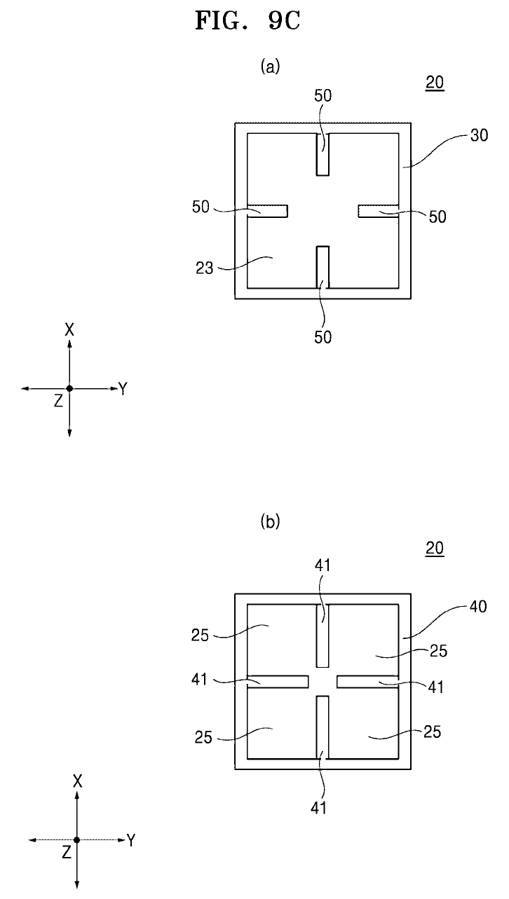

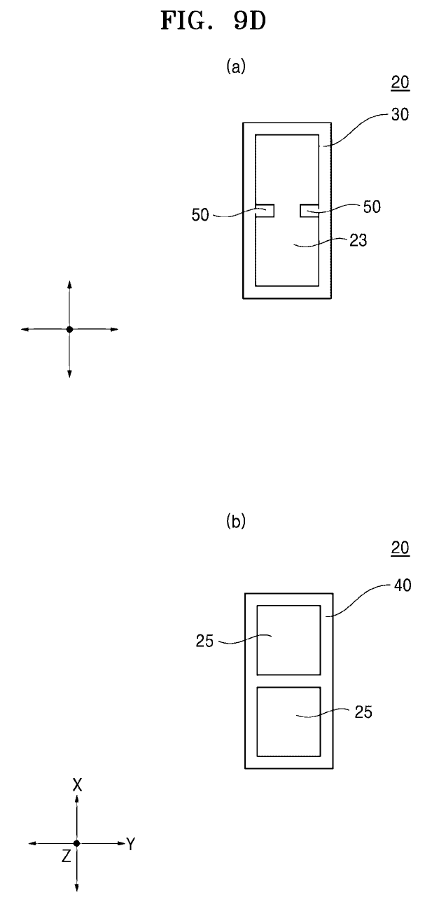

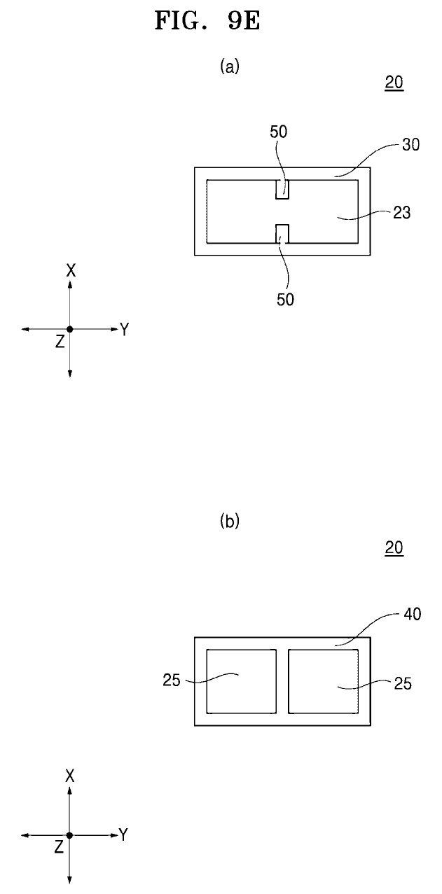

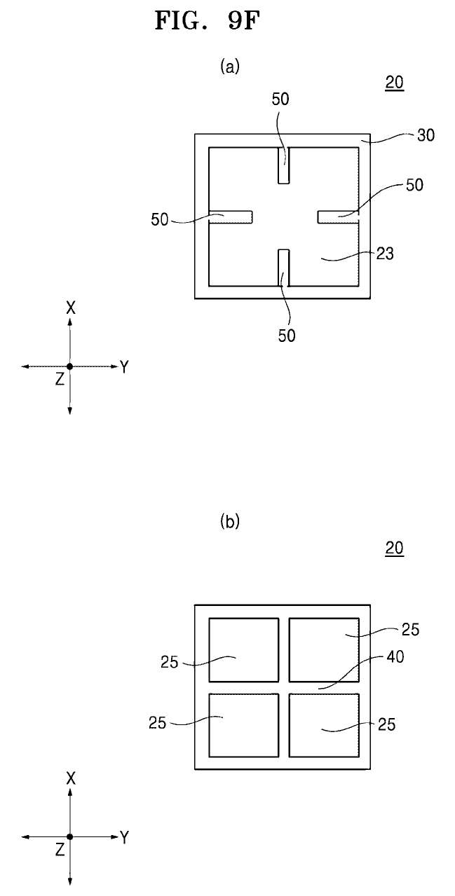

FIGS. 9A to 9F each illustrate a configuration example of the phase difference-detection pixel 20. FIGS. 9A to 9F each illustrate the light transmission layer 23 ((a) of FIGS. 9A to 9F) and the photoelectric conversion unit 25 ((b) of FIGS. 9A to 9F) to clarify the structure of the phase difference-detection pixel 20. In addition, the phase difference-detection pixel 20 may employ a configuration other than the configuration examples illustrated in FIGS. 9A to 9F. In the implementations illustrated by FIGS. 9A to 9F, the X-axis direction may be the second direction, and the Y-axis direction may be the first direction.

In the structure in which the photoelectric conversion unit 25 is divided into two parts (upper and lower parts) in the horizontal direction (X-axis direction) that is the first direction, the light separation wall 50 may be formed in accordance with the boundary separation wall 41, as illustrated in FIG. 9A.

In the structure in which the photoelectric conversion unit 25 is divided into two parts (left and right parts) in the vertical direction (Y-axis direction) that is the second direction, the light separation wall 50 may be formed in accordance with the boundary separation wall 41, as illustrated in FIG. 9B.

In the structure in which the photoelectric conversion unit 25 is divided into four parts in the horizontal direction (X-axis direction) that is the first direction and in the vertical direction (Y-axis direction) that is the second direction, the light separation wall 50 may be formed in accordance with the boundary separation wall 41, as illustrated in FIG. 9C.

When the phase difference-detection pixel 20 has an area which has a length corresponding to one pixel 10 in the horizontal direction (X-axis direction) that is the first direction (for example, 1 time the pitch of the pixel 10) and a length corresponding to two pixels in the vertical direction that is the second direction (for example, 2 times the pitch of the pixel 10), the light separation wall 50 may be formed in accordance with the pixel separation wall 40 in consideration of the size of the photoelectric conversion unit 25, as illustrated in FIG. 9D.

When the phase difference-detection pixel 20 has an area (pixel size) which has a length corresponding to two pixels 10 in the horizontal direction (X-axis direction) that is the first direction and a length corresponding to one pixel 10 in the vertical direction (Y-axis direction) that is the second direction, the light separation wall 50 may be formed in accordance with the pixel separation wall 40 in consideration of the size of the photoelectric conversion unit 25, as illustrated in FIG. 9E.

When the phase difference-detection pixel 20 has an area (pixel size) which has a length corresponding to two pixels 10 in the horizontal direction (X-axis direction) that is the first direction and a length corresponding to two pixels 10 in the vertical direction (Y-axis direction) that is the second direction, the light separation wall 50 may be formed in accordance with the pixel separation wall 40 in consideration of the size of the photoelectric conversion unit 25, as illustrated in FIG. 9F.

As illustrated in the FIGS. 9A to 9C, the light separation wall 50 may be formed shorter than the boundary separation wall 41 in a plan view under the assumption that the light intensity distribution of light passing through the light transmission layer may be wider than the light intensity distribution of the light condensed by the on-chip lens 21 on a surface of the photoelectric conversion unit 25. However, the light separation wall 50 and the boundary separation wall 41 may have the same length, depending on the length of the boundary separation wall 41.

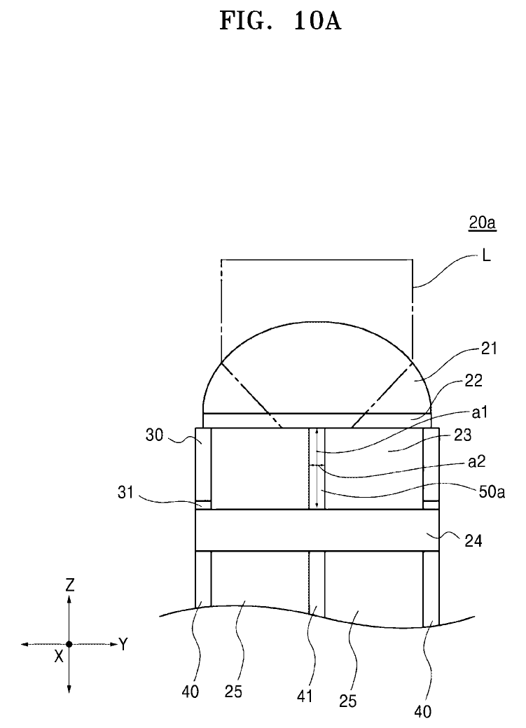

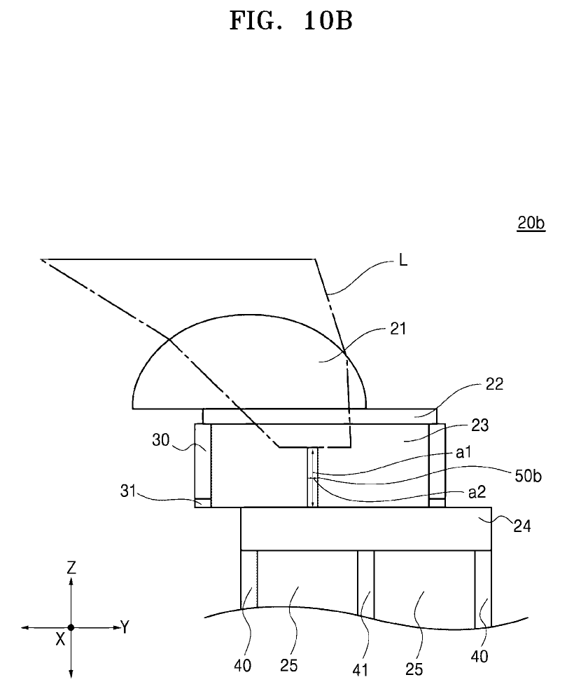

FIG. 10A is a schematic diagram of a phase difference-detection pixel 20aarranged at a central portion of a pixel array according to some implementations and FIG. 10B is a schematic diagram of a phase difference-detection pixel 20barranged at a peripheral portion of a pixel array according to some implementations.

The pupil correction amount of the phase difference-detection pixels 20a and 20b may be different at the central portion 110a and the peripheral portion 110b of the pixel array 110. Accordingly, the arrangement, width, height, etc. of the light separation walls 50a and 50b may be changed properly in the pixel according to the pupil correction amount, as illustrated in FIGS. 10A and 10B. At least one of the height and the width of the light separation walls 50a and 50b may vary according to an incident angle of light. Furthermore, the arrangement position of the light separation walls 50a and 50b in the phase difference-detection pixels 20a and 20b may vary according to an incident angle of light.

In some implementations, in the phase difference-detection pixel 20a arranged at the central portion 110a of the pixel array 110, the height of the light separation wall 50a may be the same as the height of the light transmission layer separation wall 30, and in the phase difference-detection pixel 20barranged at the peripheral portion 11b of the pixel array 110, the height of the light separation wall 50b may be lower than the height of the light transmission layer separation wall 30. In some implementations, the height of the light separation wall may decrease as the distance of the phase difference-detection pixel from the central portion 110a of the pixel array 110 increases.

In some implementations, in the phase difference-detection pixel 20a arranged at the central portion 110a of the pixel array 110, the width of the light separation wall 50a may be the same as the width of the light transmission layer separation wall 30, and in the phase difference-detection pixel 20barranged at the peripheral portion 11b of the pixel array 110, the width of the light separation wall 50b be narrower than the height of the light transmission layer separation wall 30. In some implementations, the width of the light separation wall may narrow as the distance of the phase difference-detection pixel from the central portion 110a of the pixel array 110 increases.

In some implementations, in the phase difference-detection pixel 20aarranged at the central portion 110a of the pixel array 110, the light separation wall 50a may be disposed at the center of the phase difference-detection pixel 20a. In the phase difference-detection pixel 20barranged at the periphery 110b of the pixel array 110, the light separation wall 50b may be disposed to be shifted from the center of the phase difference-detection pixel 20btoward the central portion 110a of the pixel array 110. In some implementations, the position of the light separation wall may be further shifted within the phase difference-detection pixel toward the central portion 110a of the pixel array 110 as the distance of the phase difference-detection pixel from the central portion 110a of the pixel array 110 increases.

As illustrated in FIG. 10B, the height of the light separation wall 50b may be formed to be lower than that of the light transmission layer separation wall 30 based on the pupil correction amount. Moreover, the width of the light separation wall 50b may be formed to be less than that of the light transmission layer separation wall 30, and the position of the light separation wall 50b may be moved slightly to the left (towards the central portion of the pixel array 110) according to the pupil correction amount of the on-chip lens 21. In FIGS. 10A and 10B, the height of the light separation walls 50a and 50b may be the thickness of the light separation walls 50a and 50b, denoted by an arrow A1, and the width of the light separation walls 50a and 50b may be the width of the light separation walls 50a and 50b in a direction perpendicular to the extending direction of the light separation walls 50a and 50b, denoted by an arrow A2.

As such, in the solid-state imaging device 1, as the light separation wall 50 is formed according to a pupil correction amount or an image height (for example, the radius from the center of the pixel array 110) of the phase difference-detection pixel 20, the light separation wall 50 may have an optimized structure with respect to an incident angle of the incident light L, which leads to improved separation ratio.

Hereinafter, implementations of the light separation wall 50 are described. The implementations described below may be combined properly without departing from the technical scope of the disclosure.

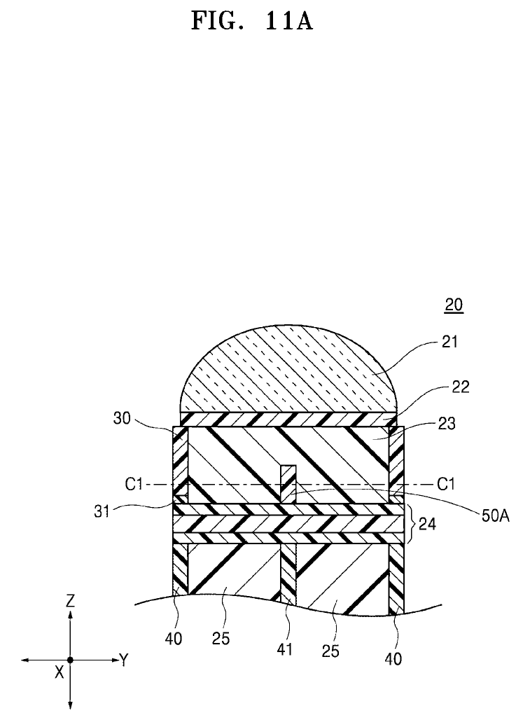

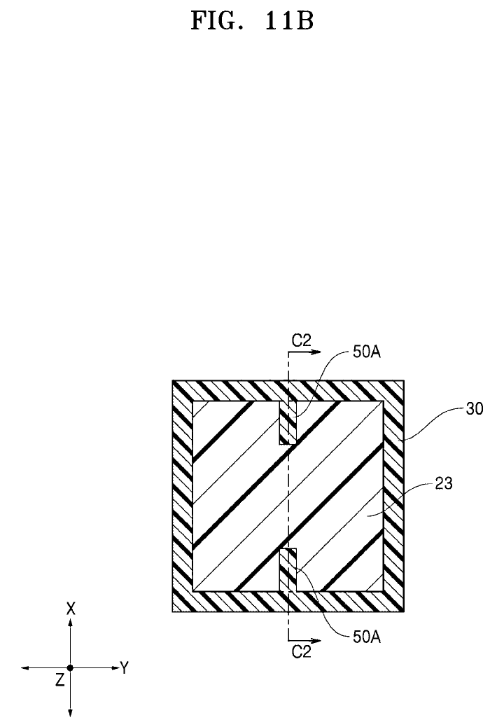

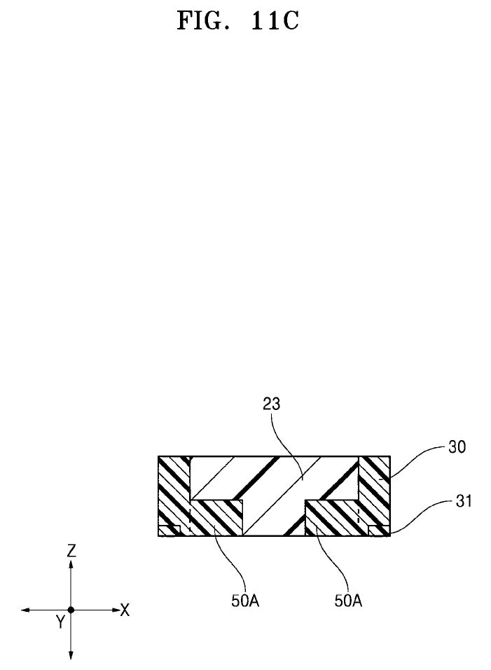

FIGS. 11A to 11C each illustrate the solid-state imaging device 1 including a light separation wall 50A according to some implementations. FIG. 11A is a schematic cross-sectional view of the solid-state imaging device 1 including the light separation wall 50A according to some implementations. FIG. 11B is a schematic cross-sectional view of the solid-state imaging device 1 taken along line C1-C1 of FIG. 11A. FIG. 11C is a schematic cross-sectional view of the solid-state imaging device 1 taken along line C2-C2 of FIG. 11B. For convenience, components arranged below the light separation wall 50A are omitted in FIG. 11C.

When the light separation wall 50 has a height at which light collection by the on-chip lens 21 is not performed sufficiently, the incidence of the incident light L may be hindered. To avoid this, the height of the light separation wall 50A may be lower than the height of the light transmission layer separation wall 30, as illustrated in FIG. 11A. In addition, as the light separation wall 50A is formed in a divided manner at the central portion of the phase difference-detection pixel 20, as illustrated in FIGS. 11B and 11C, the optical path of the incident light L incident onto the center of the pixel may be suppressed. By employing the light separation wall 50A, the solid-state imaging device 1 according to some implementations may improve the separation ratio while suppressing the sensitivity degradation by the light separation wall 50A.

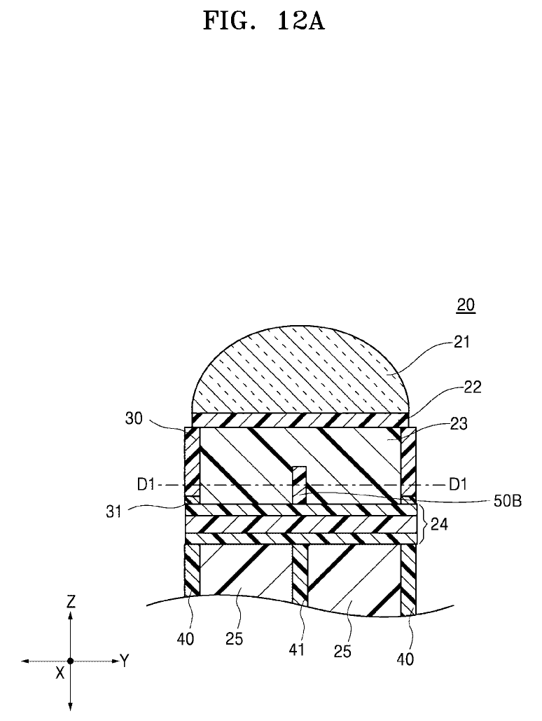

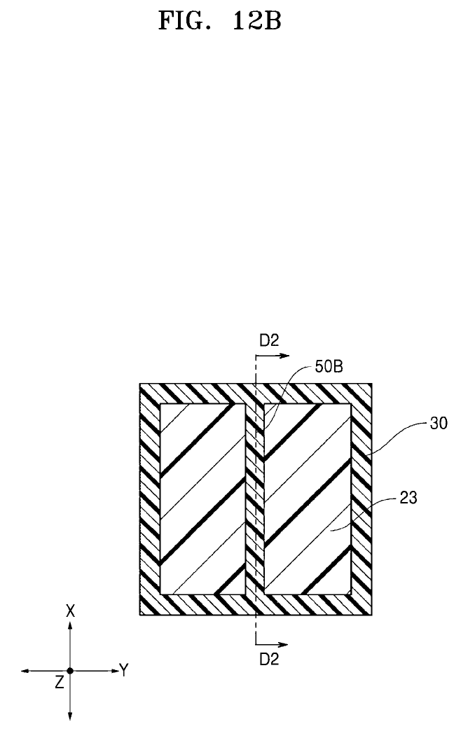

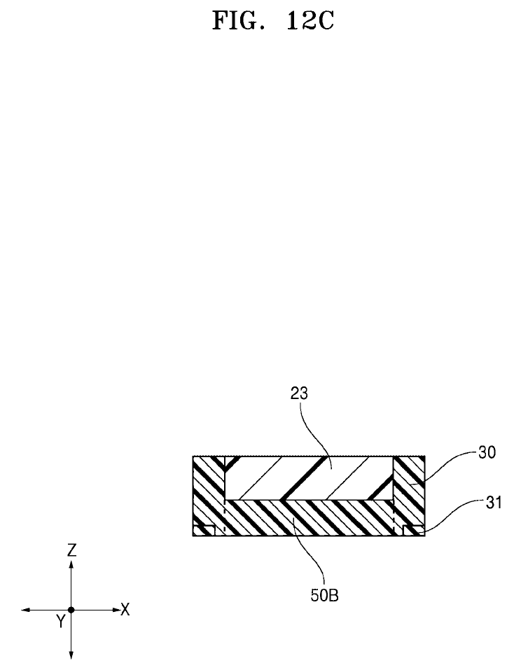

FIGS. 12A to 12C each illustrate the solid-state imaging device 1 including a light separation wall 50B according to some implementations. FIG. 12A is a schematic cross-sectional view of the solid-state imaging device 1 including the light separation wall 50B according to some implementations. FIG. 12B is a schematic cross-sectional view of the solid-state imaging device 1 taken along line D1-D1 of FIG. 12A. FIG. 12C is a schematic cross-sectional view of the solid-state imaging device 1 taken along line D2-D2 of FIG. 12B. For convenience, components arranged below the light separation wall 50B are omitted in FIG. 12C.

The height of the light separation wall 50B may be lower than the height of the light transmission layer separation wall 30, as illustrated in FIG. 12A. In addition, when the height of the light separation wall 50B is low enough to avoid blocking of the optical path of the incident light L, the light separation wall 50B may be formed continuously without being divided at the central portion of the phase difference-detection pixel 20, as illustrated in FIGS. 12B and 12C. That is, the light separation wall 50B may have a structure crossing the phase difference-detection pixel 20, as illustrated in FIGS. 12B and 12C. By employing the light separation wall 50B, the solid-state imaging device 1 according to some implementations may improve the separation ratio while suppressing the sensitivity degradation by the light separation wall 50B.

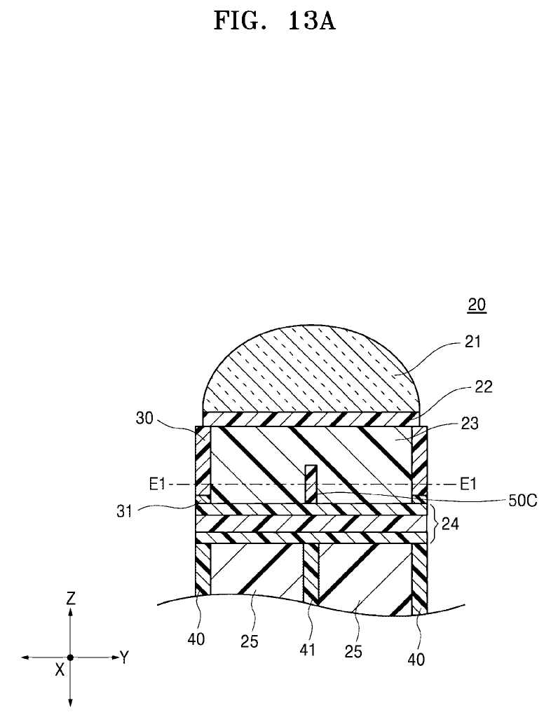

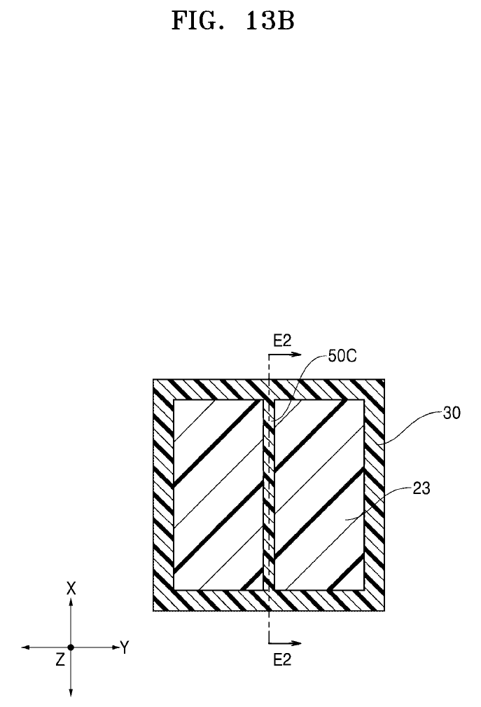

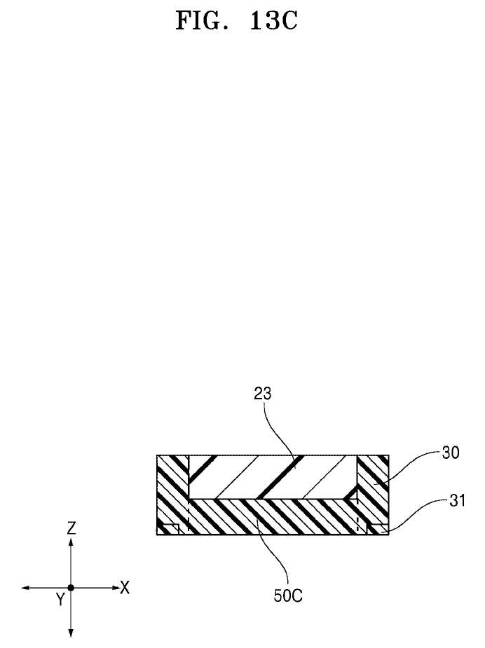

FIGS. 13A to 13C each illustrate the solid-state imaging device 1 including a light separation wall 50C according to some implementations. FIG. 13A is a schematic cross-sectional view of the solid-state imaging device 1 including the light separation wall 50C according to some implementations. FIG. 13B is a schematic cross-sectional view of the solid-state imaging device 1 taken along line E1-E1 of FIG. 13A. FIG. 13C is a schematic cross-sectional view of the solid-state imaging device 1 taken along line E2-E2 of FIG. 13B. For convenience, components arranged below the light separation wall 50C are omitted in FIG. 13C.

The light separation wall 50C in this implementation is modified from the light separation wall 50B of FIG. 12, and the width of the light separation wall 50C may be less than the width of the light transmission layer separation wall 30, as illustrated in FIGS. 13A and 13B. In addition, the height of the light separation wall 50C may be lower than the height of the light transmission layer separation wall 30, as illustrated in FIG. 13A. As illustrated in FIGS. 13B and 13C, the light separation wall 50C may be formed continuously without being divided at the central portion of the phase difference-detection pixel 20. The width of the light separation wall 50 may be set properly according to the specifications of the solid-state imaging device 1, such as a pixel size of the phase difference-detection pixel 20, an image height from the center of the pixel array 110, etc. By employing the light separation wall 50C, the solid-state imaging device 1 according to some implementations may improve the separation ratio while suppressing the sensitivity degradation by the light separation wall 50C.

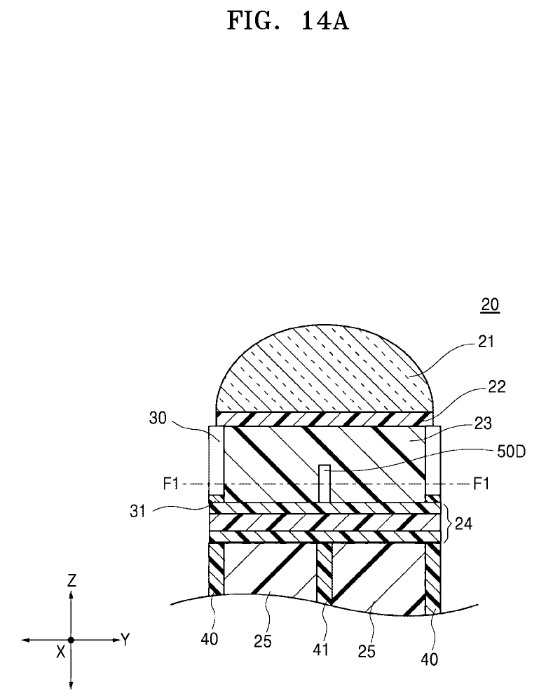

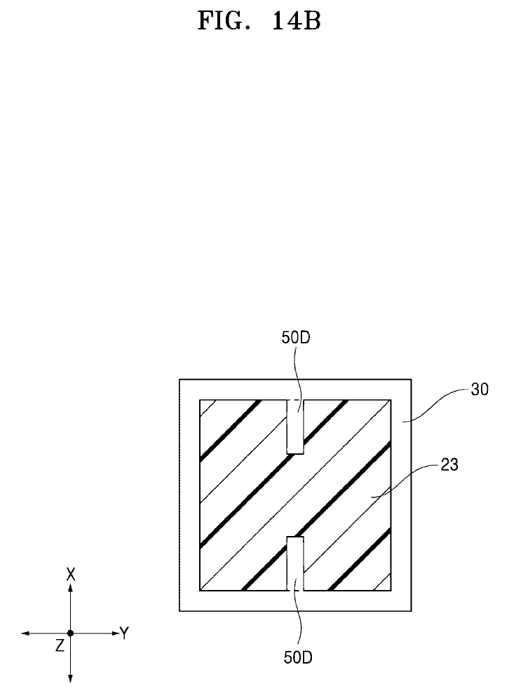

FIGS. 14A and 14B each illustrate the solid-state imaging device 1 including a light separation wall 50D according to some implementations. FIG. 14A is a schematic cross-sectional view of the solid-state imaging device 1 including the light separation wall 50D according to some implementations. FIG. 14B is a schematic cross-sectional view of the solid-state imaging device 1 taken along line F1-F1 of FIG. 14A.

In the solid-state imaging device 1, the light transmission layer separation wall 30 and the light separation wall 50D may be formed by using a cavity portion. The cavity portion may have a lower refractive index than the light transmission layer 23 and may include an air layer or a vacuum layer that has a refractive index of 1. In the solid-state imaging device 1, as the optical waveguide structure is formed by the light transmission layer 23, which has a high refractive index, and the light transmission layer separation wall 30 or the light separation wall 50D, which has a low refractive index, the incident light L may be trapped in the light transmission layer 23. The solid-state imaging device 1 may improve the separation ratio by employing the light separation wall 50D of this implementation.

As described above, the solid-state imaging device 1 according to the implementations of the disclosure may include the pixel array 110 in which the plurality of pixels 10 generating electrical signals according to the incident light L and one or more phase difference-detection pixels 20 are arranged in a matrix, wherein the phase difference-detection pixel 20 may include the photoelectric conversion unit 25, the on-chip lens 21 arranged on an incident side of the incident light L with respect to the photoelectric conversion unit 25, the light transmission layer 23 transmitting light having a particular wavelength from the incident light L, the anti-reflection layer 24 stacked on the photoelectric conversion unit 25, the light transmission layer separation wall 30 arranged between the light transmission layer 23 and a light transmission layer 23 of an adjacent pixel, the pixel separation wall 40 arranged between the photoelectric conversion unit 25 and a photoelectric conversion unit 25 of an adjacent pixel, the boundary separation wall 41 dividing the photoelectric conversion unit 25 surrounded by the pixel separation wall 40 into a plurality of parts, and a light separation wall 50 arranged between the on-chip lens 21 and the photoelectric conversion unit 25, and wherein the light separation wall 50 may be arranged parallel with the extension direction of the boundary separation wall 41 on a plane perpendicular to the stacking direction in the phase difference-detection pixel 20.

By the foregoing components, in the solid-state imaging device 1 including the light separation wall 50, the optical waveguide structure guiding the incident light L to the photoelectric conversion unit 25 may be formed at the light transmission layer 23, which has a high refractive index, and the light transmission layer separation wall 30 and the light separation wall 50, which have a low refractive index. Accordingly, in the solid-state imaging device 1, the optical path of the incident light L may be properly separated by the optical waveguide structure described above prior to the incidence onto the photoelectric conversion unit 25, the separation ratio may be improved.

Hereinafter, simulation results for evaluating the separation ratios of the phase difference-detection pixels of the solid-state imaging device according to some implementations and a solid-state imaging device according to a comparative example are described. The simulation was conducted by using Rsoft (product of Synopsis), and the quantum efficiency in the photoelectric conversion units of the green pixel was calculated by the finite-difference time-domain (FDTD) method. The wavelength of the incident light was 530 nm, and the incident angle was 10°.

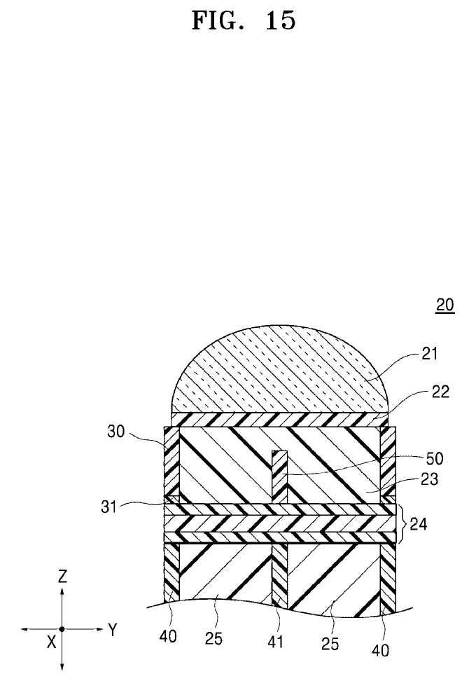

As illustrated in FIG. 15, the phase difference-detection pixel 20 according to some implementations may include the light separation wall 50 arranged on the anti-reflection layer 24. The height of the light separation wall 50 was lower than or equal to half of the height of the light transmission layer. The width of the light separation wall 50 and the width of the light transmission layer separation wall 30 were each set as 1/10 of the pixel size. The light separation wall 50 was arranged parallel with the boundary separation wall 41 in a plane direction perpendicular to the stacking direction.

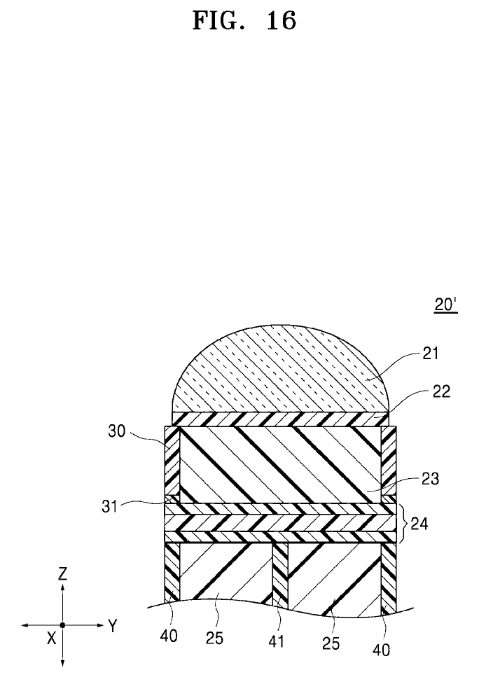

A phase difference-detection pixel 20' according to the comparative example may not include the light separation wall 50, as illustrated in FIG. 16. Other components of the phase difference-detection pixel 20' according to the comparative example were the same as those of the phase difference-detection pixel 20 according to some implementations.

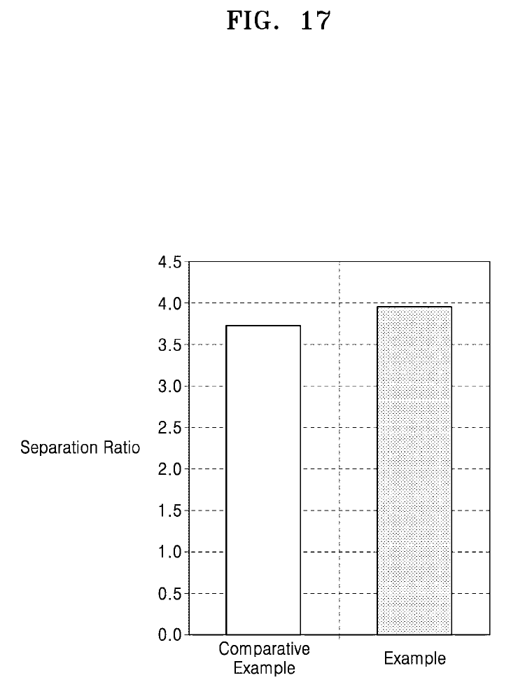

FIG. 17 is a graph showing the simulation results of the phase difference-detection pixel 20 according to some implementations and the phase difference-detection pixel 20' according to the comparative example. As illustrated in FIG. 17, the separation ratio may be improved more in the implementation in which the light separation wall is formed, compared to the comparative example that does not include the light separation wall.

From the result described above, it is found that when the light separation wall is formed between the photoelectric conversion unit and the on-chip lens of the phase difference-detection pixel in the solid-state imaging device, the optical path of the incident light may be properly divided before the incident light is incident onto the photoelectric conversion unit. Accordingly, the light separation wall may be effective at improving the separation ratio in the phase difference-detection pixel.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the concept discussed herein has been particularly shown and described with reference to implementations thereof, it will be understood that various changes in form and details may be made therein without departing from the spirit and scope of the following claims.

What is claimed is:

1. A solid-state imaging device comprising a pixel array comprising a plurality of pixels configured to generate image signals according to incident light and one or more phase difference-detection pixels arranged in a matrix,
wherein each phase difference-detection pixel of the one or more phase difference-detection pixels comprises:
a photosensor;
an on-chip lens disposed over the photosensor and configured to receive the incident light;
a light transmission layer configured to transmit light having a particular wavelength of the incident light;
an anti-reflection layer on the photosensor;
a light transmission layer separation wall between the light transmission layer and an adjacent light transmission layer of an adjacent pixel;
a pixel separation wall between the photosensor and an adjacent photosensor of the adjacent pixel;
a boundary separation wall configured to divide the photosensor surrounded by the pixel separation wall into a plurality of parts; and
a light separation wall between the on-chip lens and the photosensor,
wherein the light separation wall is parallel with an extension direction of the boundary separation wall and is positioned on a plane that is perpendicular to a stacking direction of the phase difference-detection pixel.

2. The solid-state imaging device of claim 1, wherein the light separation wall includes a dielectric material or a cavity portion that has a light absorption amount that is less than a light absorption amount of the light transmission layer.

3. The solid-state imaging device of claim 1, wherein the light separation wall includes a material having a refractive index that is lower than a refractive index of the light transmission layer.

4. The solid-state imaging device of claim 1, wherein a height of the light separation wall is less than a height of the light transmission layer separation wall.

5. The solid-state imaging device of claim 1, wherein the light separation wall is divided at a central portion of the phase difference-detection pixel.

6. The solid-state imaging device of claim 1, wherein the light separation wall intersects the light transmission layer on the plane, and wherein a height of the light separation wall is less than a height of the light transmission layer separation wall.

7. The solid-state imaging device of claim 1, wherein a width of the light separation wall is less than a width of the light transmission layer separation wall.

8. The solid-state imaging device of claim 1, wherein at least one of a height or a width of the light separation wall is based on an incident angle of light.

9. The solid-state imaging device of claim 1, wherein a position of the light separation wall in the phase difference-detection pixel is based on an incident angle of light.

10. The solid-state imaging device of claim 1, wherein an area of the phase difference-detection pixel is equal to an area of a pixel in the plurality of pixels.

11. The solid-state imaging device of claim 1, wherein an area of the phase difference-detection pixel is based on a length of two pixels in a first direction on the plane and a length of two pixels in a second direction that is perpendicular to the first direction.

12. The solid-state imaging device of claim 1, wherein an area of the phase difference-detection pixel is based on a length of one pixel in a first direction on the plane and a length of two pixels in a second direction that is perpendicular to the first direction.

13. A solid-state imaging device comprising a pixel array comprising a plurality of phase difference-detection pixels,
wherein each phase difference-detection pixel of the plurality of phase difference-detection pixels comprises:
an on-chip lens configured to condense incident light;
a light transmission layer configured to transmit light having a particular wavelength of the incident light transmitted through the on-chip lens;
a photodiode configured to photoelectrically covert light transmitted through the light transmission layer;
an anti-reflection layer between the light transmission layer and the photodiode;
a light transmission layer separation wall between the light transmission layer and a light transmission layer of an adjacent pixel;
a pixel separation wall between the photodiode and a photodiode of an adjacent pixel;
a light separation wall configured to divide the light transmission layer into at least two parts; and
a boundary separation wall configured to separate the photodiode into at least two parts.

14. The solid-state imaging device of claim 13, wherein the on-chip lens, the light transmission layer, the photodiode, and the anti-reflection layer are stacked in a first direction, and
the light separation wall is parallel with an extension direction of the boundary separation wall and is positioned on a plane that is perpendicular to the first direction.

15. The solid-state imaging device of claim 14, wherein the light separation wall is divided into at least two parts at a center of the light transmission layer on the plane, and wherein the at least two parts of the light separation wall are each connected to the light transmission layer separation wall.

16. The solid-state imaging device of claim 14, wherein the light separation wall intersects the light transmission layer on the plane, and wherein a height of the light separation wall is less than a height of the light transmission layer separation wall.

17. The solid-state imaging device of claim 14, wherein, in a first phase difference-detection pixel at a central portion of the pixel array, from among the plurality of phase difference-detection pixels, a height of the light separation wall is identical to a height of the light transmission layer separation wall,
wherein in a second phase difference-detection pixel at a peripheral portion of the pixel array, from among the plurality of phase difference-detection pixels, a height of the light separation wall is less than a height of the light transmission layer separation wall, and
wherein the height is a length in the first direction.

18. The solid-state imaging device of claim 14, wherein, in a first phase difference-detection pixel at a central portion of the pixel array, from among the plurality of phase difference-detection pixels, a width of the light separation wall is identical to a width of the light transmission layer separation wall,
wherein in a second phase difference-detection pixel at a peripheral portion of the pixel array, from among the plurality of phase difference-detection pixels, a width of the light separation wall is less than a width of the light transmission layer separation wall, and
wherein the width is a length in a direction perpendicular to the extension direction.

19. The solid-state imaging device of claim 14, wherein, in a first phase difference-detection pixel at a central portion of the pixel array, from among the plurality of phase difference-detection pixels, the light separation wall is at a center of the first phase difference-detection pixel, and
wherein for a second phase difference-detection pixel in a peripheral portion of the pixel array, from among the plurality of phase difference-detection pixels, a position of the light separation wall is offset from a center of the second phase difference-detection pixel toward the central portion of the pixel array.

20. The solid-state imaging device of claim 13, wherein the pixel array comprises a plurality of general pixels that have a structure different from a structure of the plurality of phase difference-detection pixels and are configured to generate image signals.
